(19) United States
(12) Patent Application Publication
(10) Pub. No.: US 2026/0173878 A1
(43) Pub. Date: Jun. 18, 2026

(54) SHIELDING MESH TO REDUCE SIGNAL CROSSTALK IN CHIPLET PACKAGING

(71) Applicant: International Business Machines Corporation, Armonk, NY (US)

(72) Inventors: Nilanka W Sirikkathuge, Guilderland, NY (US); Tao Li, Slingerlands, NY (US); Qianwen Chen, Fort Collins, CO (US); Joshua Mark Rubin, Albany, NY (US); Ruilong Xie, Niskayuna, NY (US)

(21) Appl. No.: 18/979,870

(22) Filed: Dec. 13, 2024

(51) Int. Cl. H01L 23/58; H01L 25/065

(52) U.S. Cl. CPC H10W 42/00; H10W 90/00

(57) ABSTRACT

An electromagnetic (EM) shield for a semiconductor chiplet composed of frontside interconnect metal layers forming a top metal mesh above the surface of the chiplet and backside interconnect metal layers to form a metal mesh below the chiplet surface. The shield further includes a through-insulator-via (TIV) at a crack stop location of the chiplet that connect the top metal mesh to the bottom metal mesh. Alternatively, the EM shield can include a top metal plate above the top surface of the chiplet and a bottom metal plate below the bottom surface of the chiplet and includes vertical TIVs at die sidewall edges. Further, the top metal and bottom plates can each be co-integrated with a respective mid-via MIM capacitor respectively located between two frontside and two backside interconnect metal levels. The shield is tamperproof preventing attacks and probing and is connected to isolated BEOL layers separate from a power grid.

### BACKGROUND

This disclosure relates generally to semiconductor chips or dies including multilayer high density chip/chiplet stacks, and more specifically to a novel shielding mesh structure to reduce electromagnetic interference in chip/chiplet packaging and enable security from external attacks.

Multi-functional and small form factor chips can be realized using through silicon via (TSV)-based, three-dimensional (3D) integrated circuits (ICs). For example, some 3D mixed signal systems include a logic IC coupled to an RF/analog IC in a vertical stack. In such vertically stacked semiconductor chips/chiplets, the distance between the RF/analog IC and logic IC is reduced to a few tens of micrometers (μm), e.g., by the back-grinding of the silicon substrate for the TSV connection. Due to the close proximity of two ICs, unwanted vertical noise coupling that is caused by the near field coupling between the RF/analog IC and the logic IC can be a severe problem. Therefore, a shielding material to reduce the vertical noise coupling is required.

Furthermore, closer proximity of chiplets in 2.5/3D designs enables probing and/or side channel attacks within the designs. EMI shielding can protect a chiplet from some forms of attack/probing.

### SUMMARY

Embodiments of the present disclosure provide a metal shielding apparatus for a chiplet die formation, the metal shielding apparatus disposed above and below top and bottom die surfaces and configured to reduce electromagnetic (EM) signal coupling to an adjacent power grid.

In an embodiment, the chiplet die is shielded by a metal mesh or a metal plate disposed above and below the die surfaces in interlevel dielectric materials layers inside Back-End-Of-Line (BEOL) semiconductor manufacturing layers.

In one aspect of this embodiment, the metal mesh on top of the die includes one of the frontside interconnect metal layers, and the metal mesh at the bottom of the die is composed of one of the backside interconnect metal layers.

In an embodiment, the chiplet die is further shielded along opposing die sidewall edges by through insulator vias (TIVs) at a crack stop region on opposing sides of the die, the TIV connecting with the metal mesh or metal plate shielding structure.

In an embodiment, the metal mesh or a metal plate shielding structure is co-integrated with a metal-insulator-metal (MIM) capacitor at a die top and bottom. The metal shielding apparatus co-integrated with the MIM capacitor and together with TIVs fabricated around the die sidewall edges can form EMI shielding for the whole die/chiplet and prevent the whole chiplet die from some forms of probing attack and probing not only from the sidewalls, but also from surfaces.

In a further aspect of this embodiment, the metal mesh on top of the die includes a first metal plate connected to a MIM capacitor located between two far frontside interconnect metal levels, and the metal mesh at the bottom of the die includes a second metal plate connected to a MIM capacitor located between two far backside interconnect metal levels. The metal plate co-integrated with the MIM capacitor provides a resistive or resistive and capacitive EM shield that can be sensed by on-chip circuits.

The EM shield provides a resistance and capacitance tamper detection layer that can be sensed by on-chip circuits for interference/tampering and physical modification.

In one aspect, there is provided an electromagnetic (EM) shielding apparatus for a semiconductor die. The EM shielding apparatus includes: a top metal shield structure disposed in an interlevel dielectric material layer above a top surface of the semiconductor die, the top metal shield structure disposed at a frontside metal interconnect level within the interlevel dielectric material layer, the interlevel dielectric material layer comprising a low-k dielectric material; a bottom metal shield structure disposed in an interlevel dielectric material layer below a bottom surface of the semiconductor die, the bottom metal shield structure disposed at a backside metal interconnect level; and a side metal via having a first connection to the top metal shield structure at the frontside metal interconnect level and a second connection to the bottom metal shield structure at the backside metal interconnect level, the side metal via extending from the top metal shield structure to the bottom metal shield structure through a dielectric material portion of the semiconductor die.

In a further aspect, there is provided an electromagnetic (EM) shielding apparatus for a semiconductor die. The EM shielding apparatus includes: a metal shield structure disposed in an interlevel dielectric material layer either above a top surface of the semiconductor die or below a bottom surface of the semiconductor die, the interlevel dielectric material layer comprising a low-k dielectric material; a first metal interconnect structure and a second metal interconnect structure, each first and second metal interconnect structure disposed spaced apart in the interlevel dielectric material layer either above the top surface or below the bottomsurface of the semiconductor die and each first and second metal interconnect structure comprising a metal layer and a metal via connected to the metal layer, the metal shield structure disposed at a height corresponding to a via-level height of the first and second metal interconnect structures formed within the interlevel dielectric material layer; and a first metal-insulator-metal capacitor (MIMcap) having a first metal plate and a second metal plate and a high-k dielectric material therebetween, the first metal plate connecting the metal via of the first metal interconnect structure and the second metal plate connecting the metal via of the second metal interconnect, the first MIMcap being disposed below the metal shield structure and separated therefrom by the low-k dielectric material.

According to a further aspect, there is provided an electromagnetic (EM) shielding apparatus for a semiconductor die. The EM shielding apparatus including: a first metal interconnect structure and a second metal interconnect structure, each first and second metal interconnect structure disposed in an interlevel dielectric material layer either above a top surface of the semiconductor die or below a bottom surface of the semiconductor die, and each first and second metal interconnect structure comprising a metal layer and a metal via connected to the metal layer, the metal shield structure disposed at a height corresponding to a via-level height of the first and second metal interconnect structure formed within the interlevel dielectric material layer; a first metal-insulator-metal capacitor (MIMcap) having a first metal plate and a second metal plate and a high-k dielectric material therebetween, the first metal plate of the first MIMcap connecting the metal via of the first metal interconnect structure and the second metal plate of the first MIMcap connecting the metal via of the second metal interconnect, the first MIMcap being disposed at the via-level height below the metal shield structure and separated therefrom by the low-k dielectric material; a third metal interconnect structure and a fourth metal interconnect structure, each third and fourth metal interconnect structure disposed spaced apart in the interlevel dielectric material layer either above the top surface of the semiconductor die or below the bottom surface of the semiconductor die and each third and fourth metal interconnect structure comprising a metal layer and a metal via connected to the metal layer; and a second metal-insulator-metal capacitor (MIMcap) having a first metal plate and a second metal plate and a high-k dielectric material therebetween, the first metal plate of the second MIMcap connecting the metal via of the third metal interconnect structure and the second metal plate of the second MIMcap connecting the metal via of the fourth metal interconnect, the second MIMcap being disposed at the via-level height below the first MIMcap and separated therefrom by the low-k dielectric material.

Further features, as well as the structure and operation of various embodiments, are described in detail below with reference to the accompanying drawings. In the drawings, like reference numbers indicate identical or functionally similar elements.

### BRIEF DESCRIPTION OF THE DRAWINGS

FIG. 1 is a cross-sectional view of a conventional chiplet stack arrangement with chiplet dies arranged in a die stack of tiers mounted on a carrier;

FIG. 2 depicts a modified die stack structure corresponding to the die stack of FIG. 1 that provides formed electromagnetic interference (EMI) shielding structures in accordance with the embodiments of the present disclosure;

FIG. 3 depicts a detailed semiconductor device including a chip/chiplet die stack including an EMI metal mesh shielding structure in accordance with a further embodiment of the present disclosure;

FIG. 4A shows a top-down view of the metal mesh shield disposed above the die of FIG. 3, and a similar mesh shield that can be disposed below the die of FIG. 3;

FIG. 4B shows a top-down view of a metal mesh EM shield consisting of a cross-hatch, honeycomb or waffle-type pattern of metal lines according to an alternative embodiment;

FIG. 5 depicts a detailed semiconductor device including a chip/chiplet die stack including an EMI metal plate shielding structure in accordance with a further embodiment of the present disclosure;

FIG. 6 shows a top-down view of the EM shield metal plate disposed above the die of FIG. 5 according to an embodiment;

FIG. 7 depicts a cross-sectional view of the chiplet die in a die stack including a mid-via metal plate in a low-k interlevel dielectric material layer above the die and including a connected metal-insulator-metal (MIM) capacitor structure in accordance with an embodiment;

FIG. 8 depicts a top view of a portion of the mid-via level EM shield metal plate that optionally includes shield perforations or openings that reduce EM shield coupling to the MIM capacitor in an embodiment;

FIG. 9 depicts a cross-sectional view of the chiplet die in a die stack including within a low-k interlevel dielectric material layer a first metal-insulator-metal (MIM) capacitor structure co-integrated with a second MIMcap in accordance with an embodiment; and

FIGS. 10A-10F depict an exemplary process for fabricating a stacked semiconductor die structure including chiplets having active devices and an attached EM shield according to embodiments herein.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

According to an aspect of the invention, there is provided an electromagnetic (EM) shielding apparatus for a semiconductor die. The EM shielding includes: a top metal shield structure disposed in an interlevel dielectric material layer above a top surface of the semiconductor die, the top metal shield structure disposed at a frontside metal interconnect level within the interlevel dielectric material layer, the interlevel dielectric material layer comprising a low-k dielectric material; a bottom metal shield structure disposed in an interlevel dielectric material layer below a bottom surface of the semiconductor die, the bottom metal shield structure disposed at a backside metal interconnect level; and a side metal via (a through-insulative-via) having a first connection to the top metal shield structure at the frontside metal interconnect level and a second connection to the bottom metal shield structure at the backside metal interconnect level, the side metal via extending from the top metal structure to the bottom metal structure through a dielectric material portion of the semiconductor die. The EM shielding apparatus shields the die from EM interference and provides a tamperproof structure.

At least one frontside metal interconnect structure is disposed in the interlevel dielectric material layer above the top surface of the semiconductor die, the frontside metal interconnect structure comprising a top metal layer and a metal via connected to the top metal layer, the top metal structure being formed at a via-level height above the top surface of the semiconductor die corresponding to the metal via connecting the top metal layer of the at least one frontside metal interconnect structure.

The top metal structure can consist of a planar mesh or a planar metal plate. The top metal structure can be perforated to reduce capacitive coupling to a power grid.

The at least one frontside metal interconnect structure consists of a first frontside metal interconnect structure and a second frontside metal interconnect structure disposed spaced apart in the interlevel dielectric material layer above the top surface of the semiconductor die and each first and second frontside metal interconnect structure comprising a top metal layer and a metal via connected to the top metal layer. The shielding further includes: a metal-insulator-metal capacitor (MIMcap) having a first metal plate and a second metal plate and a high-k dielectric material therebetween, the first metal plate connecting a metal via of the first frontside metal interconnect structure and the second metal plate connecting a metal via of the second frontside metal interconnect structure, the MIMcap being disposed below the top metal structure and separated therefrom by said low-k dielectric material. The MIMcap and top metal structure provides a resistive and capacitive tamper detection layer can be sensed by on-chip circuits for interference/tampering and physical modification.

Using a co-integrated metal plate and MIMcap and through-insulative-via side structure can form EMI shielding for the whole die/chiplet to prevent attack and probing not only from sidewall, but also from surfaces.

Further, the EM shield/tamperproof apparatus is connected to isolated BEOL layers separate from a power grid. Using a co-integrated EM shield with mid-via tamper MIM cap and a power MIMcap is a reduced cost solution. The specific designed low-K dielectric between tamper and power MIMcap can reduce coupling to an adjacent power grid.

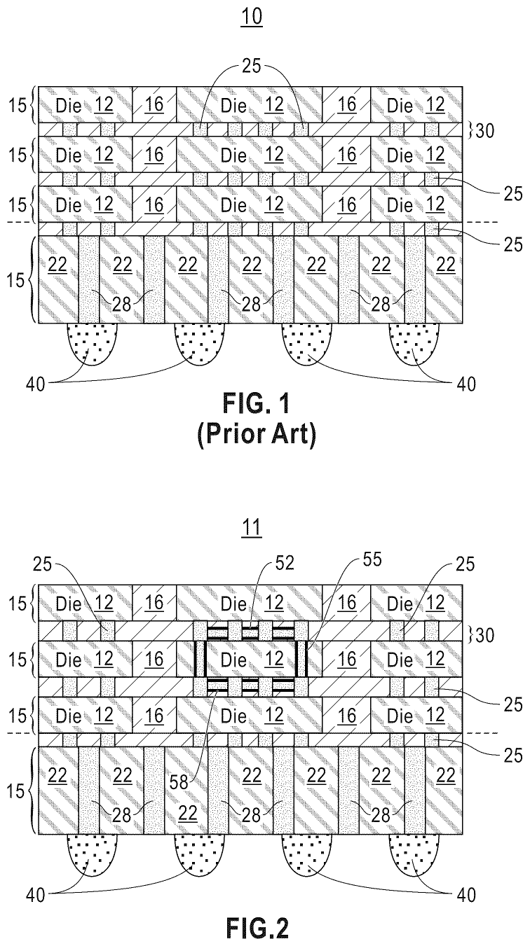

FIG. 1 depicts a semiconductor die stack structure 10 (die stack) with thin chips or chiplet dies configured as an array of dies 12 disposed in an arrangement on multiple tiers 15. As shown in FIG. 1, the die stack 10 is made with two or more layers of semiconductor dies (or chips or chiplets) that are stacked one above the other, electrically interconnected, and held together to make a single, unified semiconductor die stack structure 10. The chips or chiplets die 12 can be on the order of between 5 μm-50 μm to 200 μm thick. These dies are typically “picked and placed” to create stand-alone die structures often using thermal compression bonding or in some cases, traditional flip chip reflow assembly processes.

In FIG. 1, the die stack 10 is made of two or more tiers 15 of dies 12, each die 12 having a plurality of active devices (not shown). At each tier 15, multiple dies 12 are configured spaced apart on a substrate (not shown). On a tier 15, a die 12 can include top and bottom surfaces each having die connections 25 that are mechanically and electrically connected to other dies at a tier 15 disposed immediately above or below the die. In FIG. 1, the die connections 25 can be solder bumps, as in C4 (Controlled collapse chip connection) connections, copper pillars, copper pillars with solder tips, copper pads, or other conductive connections. The die connections 25 can be electrically and mechanically connected to “opposing” but similar connections on other devices, chips, substrates, etc. The die connection height or gap spacing 30 between successive tiers 15 can be between 10-30 microns (μm) or less, e.g., 10-20 μm, or even lower than 10 μm. If the die connections are microbumps, the gap spacing can range between 10-50 microns. If it is hybrid bonding, copper-copper bonding, or the like, the gap spacing 30 can be even smaller, e.g., with hybrid bonding there is effectively no gap as this is a BEOL layer joined to a BEOL layer on another die.

In an embodiment, a bottom tier 15 of the die stack 10 includes a substrate, a laminate or like carrier structure 22. The carrier structure (e.g., a semiconductor substrate) 22 includes through silicon vias (TSVs) 28 that electrically connect to other dies, circuits, or another die (chip/chiplet) stack. At the bottom of the carrier substrate 22 are electric contacts, e.g., C4 or solder bumps 40 providing electrical connections for mechanically and electrically bonding to other carrier structures (not shown). The multilayer high-density chip/chiplet die stacking structure 10 engenders concerns on signal crosstalk/interference for sensitive dies.

FIG. 2 depicts a modified die stack structure 11 corresponding to the die stack 10 of FIG.

1 that provides formed electromagnetic interference (EMI) shielding structures in accordance with the embodiments of the present disclosure. In particular, the die stack structure 11 of FIG. 2 includes a die 12 having a formed frontside shielding structure 52, an edge shielding structure 55, and a backside shielding structure 58. This die stack structure 11 of FIG. 2 provides a shielding mesh or plate to reduce EM interference in chip/chiplet packaging and/or enable security from external attacks/probing not only from the sidewalls, but also from surfaces.

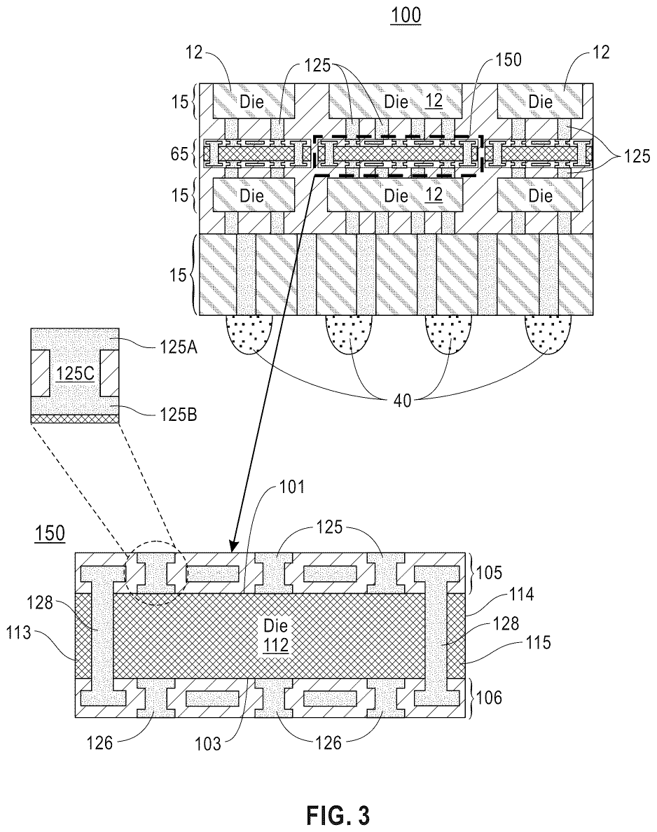

FIG. 3 depicts a detailed semiconductor device including a chip/chiplet die stack 100 including an EMI metal shielding apparatus 150 in accordance with a further embodiment of the present disclosure.

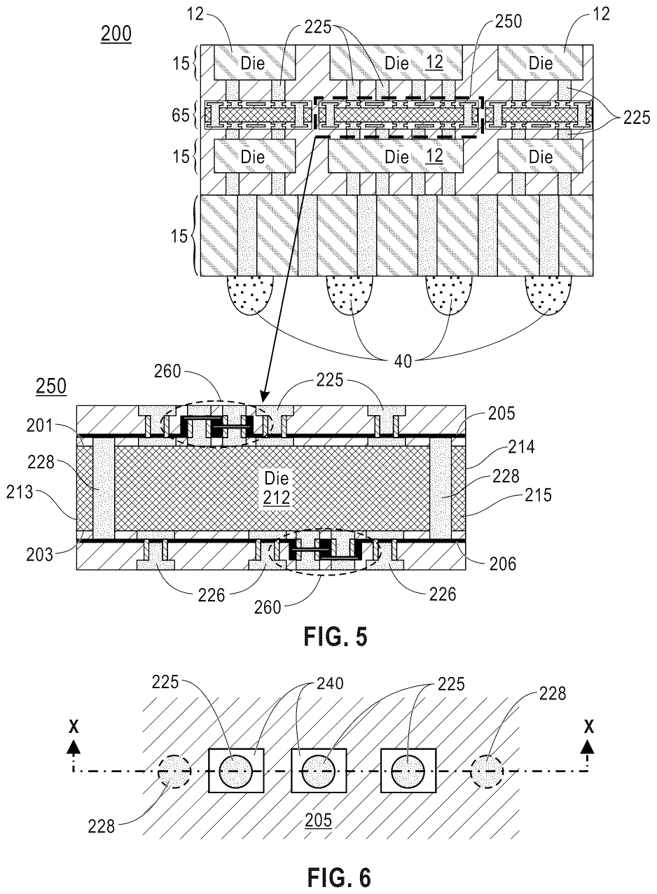

In the cross-sectional view of a first embodiment depicted in FIG. 3, there is depicted a die stack 100 corresponding to the die stack 11 of FIG. 2 having tiers 15, with each tier 15 consisting of an array of one or more chiplet dies 12. In the die stack 100, at a tier, e.g., tier 65, there is included at least one die 112 having active circuitry (e.g., transistors) and an EM metal shield 150 (at a mid-via height level) surrounding the die 112. The EM metal shield can include a metal mesh 105 or, in an alternative embodiment, a metal plate enabling resistive sensing, capacitance sensing or both capacitance and resistance sensing, e.g., to detect tampering or power integrity. In alternative embodiments, the shield 105 is co-integrated with a metal-insulator-metal (MIM) capacitor (not shown). By co-integration, it is meant that the shield 105 is integrated with MIMcap structure, whereby both structures are located between the same BEOL layers (both structures are located adjacent to one via level), such as in the embodiment depicted in FIG. 5. The EM shield can be further co-integrated with a MIMcap that is used for verifying power integrity. EM shield 150 also includes, below the die bottom surface 103, a metal mesh EM shield 106 or a metal plate, providing for resistive, capacitive, or both resistive and capacitive sensing to detect tampering or power integrity. The EM shield 106 can additionally be co-integrated with a metal-insulator-metal (MIM) capacitor (not shown). The chiplet die 112 is further shielded at or near each opposing side edge (e.g., sidewall) by through-insulator-via (TIV) structure(s) 128 running vertically along a side edge of the die at or near opposing side edges 113, 114 of the die 112. Each TIV structure 128 includes a top portion connecting to the metal mesh 105 above the die top surface and extends to below the die bottom surface and connects to the bottom metal mesh 106. In an embodiment, the TIV structure 128 is formed at a crack stop region that is located near the side edge of the die 112 or at any other location in the die. The crack stop region where a through via 128 is formed corresponds to that portion of the semiconductor chip designed to avoid crack propagation towards active chip area after chiplet die separation. In the die stack embodiment 100 depicted in FIG. 3, each metal shield 105, 106 is provided to reduce electromagnetic (EM) signal coupling to an adjacent power grid (not shown) and is disposed above and below the die in interlevel dielectric materials layers inside Back-End-Of-Line (BEOL) layers. In the embodiment depicted, at the die frontside, the metal mesh 105 above the top of the die 112 is a shield composed by one of the frontside interconnect metal layers, and at the die backside, the metal mesh 106 below the bottom of the die is a shield composed by one of the backside interconnect metal layers. In a non-limiting embodiment shown in FIG. 3, top metal mesh 105 is formed of frontside interconnects 125 that can include top and bottom metal interconnect layers 125A, 125B respectively, and one via layer 126C vertically interconnecting metal layers 125A, 125B. Similarly, the bottom metal mesh 106 is formed of backside interconnects 126 of a similar structure that includes top and bottom metal layers and one via layer vertically interconnecting the two metal layers. Further, in FIG. 3, the through-insulator-via (TIV) 128 at a crack stop region in a dielectric layer 115 is due to backside power delivery network (BSPDN) processing, where a silicon substrate has been completely removed.

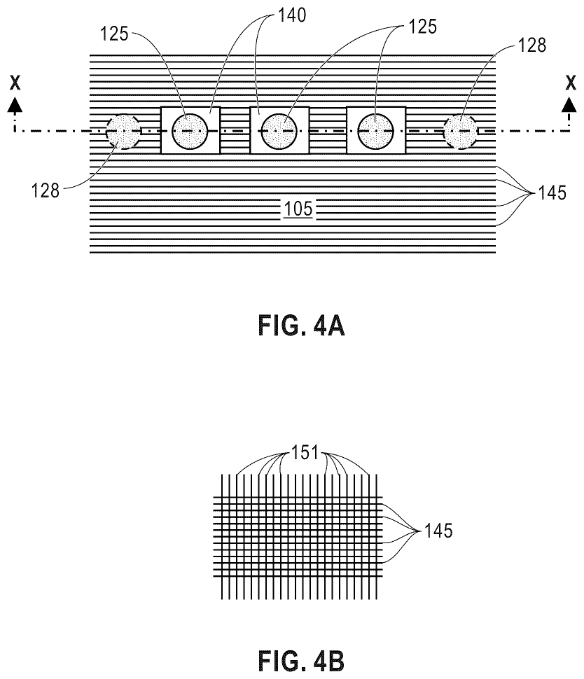

FIG. 4A shows a top-down view of the top metal mesh 105 disposed above the die 112 of FIG. 3. The bottom metal mesh 106 that is disposed below the die 112 of FIG. 3 can be a similar structure as top metal mesh 105, however they may have different patterns in accordance with signal routing requirements and other obstructions. In an embodiment, the metal mesh 105 can be a two-dimensional (2D) mesh on a single metal layer formed of orthogonal lines. Alternately, the metal mesh 105 can be composed of more than one metal layer to provide sufficient isolation (with the metal layers having an electrical connection between them using vias), such that one layer may have horizontal lines and another layer may have lines orthogonal to the first layer. In FIG. 4A, the top metal mesh 105 consists of parallel oriented frontside interconnect metal lines 145 and having formed therein openings 140 for accommodating penetration of isolated frontside interconnect metal layers 125 that connect to the die surface and extend through the opening to connect with an upper die or other upper interconnect layers. In a non-limiting embodiment, the top-down view of FIG. 4A shows the openings 140 for accommodating some of the frontside interconnect metal layers 125 in a linear arrangement (e.g., along a horizontal axis) and are further shown aligned with TIV 128 structures disposed at the sidewall the edges of the die 112 at the crack stop locations. Although not shown, the metal mesh 106 consists of parallel oriented backside interconnect metal lines and having similar openings formed therein for accommodating some isolated backside metal interconnect structures that connect to a surface of the die and extend therethrough. The metal mesh 106 can also be a 2D mesh of orthogonal lines, or be composed of more than one metal layer to provide sufficient isolation (whereby the metal layers would have an electrical connection between them using vias), such that one layer may have horizontal lines and another layer may have lines orthogonal to the first layer.

In an alternative embodiment, as shown in FIG. 4B, the respective frontside (top) and backside (bottom) 2D metal mesh 105, 106 can be configured as a 2D, single layer cross-hatch, honeycomb or waffle-type pattern consisting of horizontally oriented metal lines 145 of a frontside interconnect metal layer and connected metal lines 151 of that frontside interconnect metal layer that are oriented substantially perpendicular or at an angle relative to the metal lines 145. Alternatively, the metal mesh pattern can be three-dimensional (3D) with metal lines in more than one metal layer to provide sufficient isolation (whereby the metal layers would have an electrical connection between them using vias), such that one layer may have horizontal lines and another layer may have lines at an angle relative to lines of the first layer (not shown). In either embodiment, the wire mesh metal lines can range from between 30 nm to 100s of nanometers in width.

FIG. 5 depicts a die stack 200 of an alternate embodiment that corresponds to the die stack 100 of FIG. 3 having tiers 15, with each tier 15 consisting of an array of chiplet dies 12. In the die stack 200, at a tier, e.g., tier 65, there is included at least one die 212 having active circuitry (e.g., transistors) and a mid-via EM shield 250 surrounding the die 212. The mid-via EM shield 250 includes a shield portion disposed above a top surface 201 between two BEOL metal layers. The EM shield is a contiguous planar metal plate 205 that can be separately formed and spanning across the whole die surface or a portion thereof. Alternatively, the EM shield can constitute a top (or bottom) plate of a metal-insulator-metal (MIM) capacitor structure 260. In an embodiment shown in FIG. 5, the metal EM shield 205 is disposed below and adjacent a separately formed mid-via MIM cap and provides an EM shield enabling resistive sensing, capacitance sensing or both capacitance and resistance sensing, e.g., to detect tampering or power integrity. Alternatively, the EM shield 205 metal plate can form part of or connects to the MIM capacitor, e.g., forms an upper plate or lower plate of the MIM-cap above the die 212. That is, the EM shield 205 could be a plate of a MIMcap or it could be a discrete plate adjacent to a MIMcap. Also included, below the die bottom surface 203, is a metal EM shield 206 constituting a contiguous metal plate that can be disposed mid-via level structure providing a resistive EM shield above or below a separately formed mid-via MIMcap. Alternatively, the metal plate of EM shield can be co-integrated with the metal-insulator-metal (MIM) capacitor, i.e., forms an upper plate or lower plate of the MIM-cap below the die 212, or it could be a discrete plate adjacent to a MIMcap. The chiplet die 212 is further shielded at its sidewalls through-insulator-via structure(s) 228 running vertically at or near opposing side edges 213, 214 of the die 212. Each TIV structure 228 includes a top surface connecting to the metal plate 205 above the die top surface and extends to below the die bottom surface and connects to the bottom metal plate 206 and is located at a crack stop region of the die 212. In the die stack embodiment 200 depicted in FIG. 5, each metal shield 205, 206 is respectively disposed above and below the die in interlevel dielectric materials layers inside Back-End-Of-Line (BEOL) layers and provided to reduce electromagnetic (EM) signal coupling to an adjacent power grid (not shown). In one aspect, the metal shields 205, 206 reduce potential noise coupling (signal coupling) in the die 212 or prevent die 212 from emanating excessive noise into adjacent dies as EM signal coupling could be a problem for a given dies power grid or it could interfere with other signal nets. In the embodiment depicted, the metal plate 205 above the top of the die 212 is composed of a mid-via level frontside interconnect metal layer, and the metal plate 206 below the bottom of the die is composed of a mid-via level backside interconnect metal layer. As shown in FIG. 5, by “mid-via” it is meant that the top EM shield metal plate 205 is formed at a mid-via level height above the top surface 201 of the semiconductor die corresponding to a via-level height below a top metal layer of the frontside metal interconnect structure, i.e., with both EM shield and/or MIMcap located between the same BEOL metal layers of at least one frontside metal interconnect structure 225. In embodiments, the metal shield can be held at a constant potential, which could be a ground or a voltage.

Although not shown, in the die stack embodiment 200 depicted in FIG. 5, the metal plate 205 on top of the die 212 can be one lower plate of a connected MIM capacitor 260 located between two far frontside metal interconnect structures 225, and similarly, the metal plate 206 on the bottom of the die 212 can be one plate of a connected MIM capacitor 260 located between two far backside interconnect metal levels 226. In a non-limiting embodiment shown in FIG. 5, both the frontside metal interconnect structures 225 and backside interconnect structures 226 can include top and bottom metal interconnect layers and one via layer interconnecting the top and bottom metal layers. In an embodiment, the metal plate shield 205 is formed between two far frontside interconnect metal levels with through vias in between. The MIM cap may be formed on top of metal plate 205 and similarly a MIM cap may be formed underneath (below) bottom metal plate 206. In FIG. 5, the MIMcaps 260 are shown as formed on top of respective metal plates 205, 206 in both frontside and backside cases (e.g., given a normal process flow). Further, in FIG. 5, the die side shield structure 228 is a through-insulator-via (TIV) at a crack stop in a dielectric layer 215 due to backside power delivery network (BSPDN) processing, where the silicon substrate has been completely removed, or could be through silicon vias (TSVs) at the crack stop. That is, the TIVs 228 may be part of the crack stop or a separate structure adjacent to the crack stop, e.g., inside the crack stop. Although FIGS. 5, 6 show TIVs or TSVs 228 at the edge of the die 212, they can also be located anywhere within the die, as determined by the necessary electrical properties of the EM shield, e.g., which may require a lower resistance path between front and backside, whereby a distant connection at the edge may not be sufficient.

FIG. 6 shows a top-down view of the metal plate 205 disposed above the die 212 of FIG. 5. The bottom metal plate 206 that is disposed below the die 212 of FIG. 5 is an identical structure as top metal plate 205. In FIG. 6, the top metal plate 205 has formed therein openings 240 for accommodating isolated frontside interconnect metal structures 225 that connect to the die surface and extend and penetrate through the opening 240 to connect with an upper die or other upper interconnect layers. However, the feature that is penetrating through the plate 205 (and openings 240) is only the via portion of the frontside metal interconnect structure 225. In a non-limiting embodiment, the top-down view of FIG. 6 shows the openings 240 for accommodating some of the frontside interconnect metal structures 225 in a linear arrangement (e.g., along a horizontal axis) and are further shown aligned with TIV 228 structures disposed at the sidewall edges of the die 212 at the crack stop locations. Although not shown, the backside metal plate 206 consists of a contiguous planar metal structure having similar openings formed therein for accommodating some isolated backside interconnect metal structures (e.g., via portions of backside metal interconnects) that connect to a surface of the die and extend therethrough.

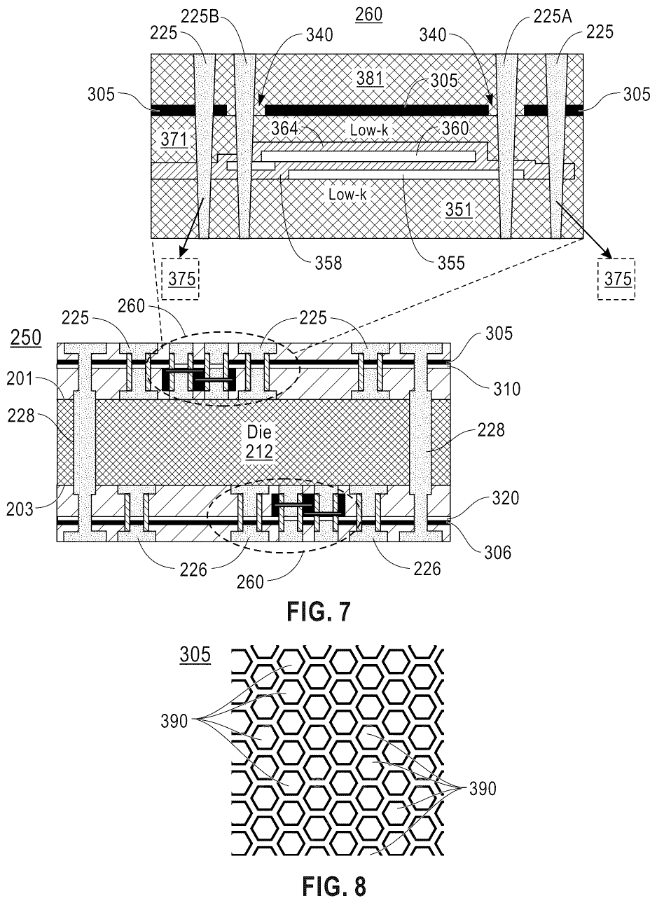

FIG. 7 depicts a detailed cross-sectional view of the chiplet die 212 in a die stack tier such as in the die stack 200 of FIG. 5 including an EM shield in the form of a “mid-via” level metal plate 305 in a low-k interlevel dielectric material layer and a separate mid-via metal-insulator-metal (MIM) capacitor structure 250 being co-integrated with both EM shield and MIMcap located between the same BEOL metal layers (at different BEOL metallization levels). In the view of FIG. 7, the mid-via metal plate 305 does not form part of a mid-via metal-insulator-metal (MIM) capacitor structure 260, but in alternative embodiments, EM shield (mid-via metal plate 305) can form one plate of the MIMcap or it could be a discrete plate adjacent to a MIMcap. Both EM shield metal plate 305 and MIMcap structure can be co-integrated whereby both structures are located between the same BEOL layers (both structures are located adjacent to one via level), such as in case of FIG. 7. In view of FIG. 7, above a top surface 201 of die 212 there is an EMI shield consisting of a mid-via metal plate 305 embedded in a low-k and/or thick inter-level dielectric material layer 310 formed above the die 212. Similarly, the die stack includes, beneath the bottom surface of die 212, a mid-via metal plate 306 embedded in a low-k and/or thick inter-level dielectric material layer 320 formed beneath the die 212. As shown in FIG. 7, by “mid-via” it is meant that the top EM shield metal plate 305 is formed at a height above the top surface 201 of the semiconductor die corresponding to a via-level height of a frontside metal interconnect structure, i.e., with both EM shield and MIMcap located between the same BEOL metal layers of at least one frontside metal interconnect structure 225. As referred to herein, BEOL layer metallization levels are formed in respective one or more interlevel dielectric (ILD) material layers that is composed of any dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” denotes a dielectric material that has a dielectric constant of less than 4.0 (all dielectric constants mentioned herein are relative to a vacuum unless otherwise noted).

As shown in the close-up view of FIG. 7, the top mid-via metal plate 305 is a separate structure not connected to the fabricated on-chip metal-insulator-metal (MIM) capacitor structure 260 that is disposed underneath. As shown in FIG. 7, on-chip access to the metal plate 305 can be had by frontside metal interconnect structures 225 that are shown connected to metal plate 305. Access to the mid-via MIMcap can be had by connections to frontside metal interconnect vias 225A, 225B that respectively contact opposing metal plates of the formed MIMcap. Similarly bottom mid-via metal plate 306 is disposed below and avoids connection with a respective mid-via MIM capacitor 260 such that the top/bottom mid-via level metal plates 305/306 is an EM shield and/or each provide a resistive, capacitive or both resistive and capacitive sensing capability for tamper detection and power integrity. Such a resistive and capacitance tamper detection shield can be sensed by on-chip circuits for interference/tampering and/or physical modification. The bottom mid-via metal plate 306 and MIMcap 260 can be co-integrated whereby both structures are located between the same BEOL layers (both structures are located adjacent to one via level). The metal plate shielding structure and MIM capacitor together with TIVs 228 fabricated around the die sidewall edges can prevent the whole chiplet die 212 from some forms of attack/probing not only from the sidewalls, but also from surfaces.

In the detailed cross-sectional view of the mid-via MIM capacitor 260, there is shown deposited a first low-k interlevel dielectric material (ILD) layer 351 within which is embedded the metallization structures forming the frontside interconnect metal layer structures 225. A patterned first metal capacitor plate electrode 355 is disposed upon the first ILD 351. A MIM capacitor high-k dielectric material layer 358 is conformally disposed over the patterned first electrode 355. The MIM capacitor first dielectric layer 358 entirely covers the patterned first electrode 355 as well as exposed portions of the first low-k ILD 351. A patterned second MIM capacitor plate electrode 360 is conformally disposed over the capacitor first dielectric layer 358 and is substantially parallel-planar with the first MIM cap electrode 355. A further high-k capacitor dielectric layer 364 is conformally disposed over the patterned second electrode 360. A second low-k interlevel dielectric (ILD) material layer 371 is disposed over the capacitor second dielectric layer 364. FIG. 7 shows a horizontal mid-via metal plate 305 formed above the second low-k interlevel dielectric (ILD) material layer 371 and a third low-k interlevel dielectric material layer 381 is disposed over the formed mid-via metal plate 305.

As further shown in the close-up view of the MIM capacitor 260 shown in FIG. 7, the vertical via portion of a frontside interconnect metal layer structure 225 electrically contacts the mid-via level metal plate 305. Additionally, the mid-via metal plate 305 is formed with perforations or openings 340 through which a frontside interconnect metal structure 225 can extend through without contacting the mid-via metal plate. For example, a via portion of a frontside interconnect metal layer structure 225A is shown extending vertically through the low-k dielectric material layer 381 and is isolated extending through opening 340 and through the second low-k dielectric material layer and electrically contacting the first MIM capacitor electrode 355. Similarly, a via portion of a frontside interconnect metal structure 225B is shown extending vertically through the low-k dielectric material layers 381 and is isolated extending through opening 340 and through low-k dielectric material layer 371 and electrically contacting the second MIM capacitor electrode 360. Both via portions of respective frontside interconnect metal structures 225A, 225B can further extend down through low-k dielectric material layer 351 for respective electrical connections to the die 212. In the close-up, cross-section view of FIG. 7, other via portions of frontside interconnect metal structures 225 are shown extending vertically through the low-k dielectric material layers 381 and electrically contact the mid-via metal plate 305 and extend down through low-k dielectric material layer 371, through portions of high-k dielectric material layers 358, 364 and through low-k dielectric material layer 351 (and possibly more BEOL interconnect layers) for connection to the die 212.

In an embodiment, the mid-via metal plate 305 and co-integrated MIM capacitor 250 provides a resistive, capacitive and/or both resistance and capacitance tamper detection/power integrity verification layer that can be sensed by on-chip circuits for interference/tampering and/or physical modification. Thus, although not shown in FIG. 7, some frontside interconnect metal structures 225 that electrically contact the mid-via level metal plate 305 can extend down to electrically contact and/or connect to a backside mid-via level metal plate 306. However, alternatively, the frontside interconnect metal structures 225 that electrically contact the mid-via level metal plate 305 can extend down to electrically contact and/or bond metal structure at surface of the die 212 that can conduct signals to an on-chip sensing circuit 375 that sense signals that can be used to detect interference/tampering and/or physical modification of the chiplet/die. The co-integration of the EM metal shield 305 and the MIMcap structure 260 separated with the low-k dielectric material layer 371 between EM shield and MIMcap with both EM shield and MIMcap located between the same BEOL metal layers reduces noise coupling to a power grid (not shown). That is, the EM shield can be wired separately from an adjacent power grid and may be sensed by circuits for interference (tampering) or the EM shield may just be connected to the backside EM metal shield. Further, the fabrication of co-integrated EM metal shield 305 and the MIMcap 260 structures is a reduced cost solution because the processes to fabricate each between a given pair of BEOL layers only has to be performed once, instead of repeating again between another pair of BEOL layers. Furthermore, not all dies have multiple BEOL layers with sufficient space to include these mid-via features. Adding additional BEOL metal layers, with MIMcap in between one pair of BEOL layers and an EM shield in between another pair would add further processing cost due to extra BEOL layers.

In a further embodiment, as shown in FIG. 8, there is depicted a top-down view of the EM shield mid-via level metal plate 305 that optionally includes shield perforations or openings 390 that reduce EM shield coupling to the MIM capacitor structure 260.

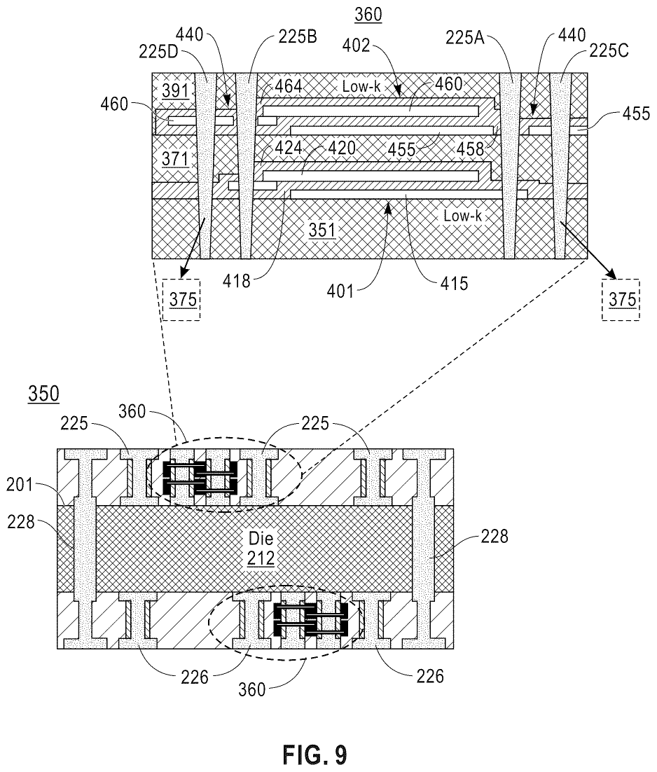

FIG. 9 depicts a detailed cross-sectional view of the EM shield 350 for a chiplet die 212 in a tier of a chiplet die stack such as in the die stack 200 of FIG. 5 including a co-integration of a first MIMcap structure formed in a low-k interlevel dielectric material layer that can serve as an EM shield and/or tampering device and a further (second) connected mid-via metal-insulator-metal (MIM) capacitor structure for power delivery/integrity with both first and second MIMcaps located between the same BEOL metal layers. In the view of FIG. 9, the two co-integrated MIMcap structures 360 are formed above a top surface 201 of die 212 embedded in a low-k and/or thick inter-level dielectric material layer 310 formed above the die 212. Similarly, the die stack includes, beneath the bottom surface of die 212, a co-integration of two MIMcap structures 360 located between the same BEOL metal layers embedded in a low-k and/or thick inter-level dielectric material layer 320 formed beneath the die 212. As shown in FIG. 9, by “mid-via” it is meant that both MIMcaps are formed at a height above the top surface 201 of the semiconductor die corresponding to a via-level height between a top metal layer and a bottom metal layer, i.e., with both MIMcaps located between the same BEOL metal layers of at least one frontside metal interconnect structure 225.

As shown in the close-up view of FIG. 9, without a separate formed top or bottom EM shield mid-via metal plate 305, 306, two MIMcaps, e.g., a “Power” MIMcap 401 and a “Tamper” MIMcap 402 are successively connecting to different frontside interconnects, e.g., located between two far frontside interconnect metal structures 225. For example, a first MIMcap 402 provides a EM shield plate 460 that is co-integrated with and formed as one plate of the fabricated MIM capacitor structure 402 with plate 455 forming the second MIMcap plate. These EM shield plates forming part of MIM capacitor structure 402 connect to frontside interconnect vias 225C, 225D which connect to a sensing circuit for tamper detection. Similarly, disposed beneath first MIMcap 402 is a second fabricated MIM capacitor structure 401 having capacitor plates 415, 420 connected to respective frontside interconnect vias 225A, 225B. While a MIMcap 401, 402 is shown having only two plates for purposes of illustration, it is understood that a given MIMcap is not so limited and can include more than two plates. As shown in FIG. 9 the similarly co-integrated bottom two mid-via MIM capacitors are configured in a similar manner between via portions of backside interconnect structures 226. When both the top and bottom mid-via level metal plates 305, 306 (FIG. 7) are co-integrated with MIMcaps 401, 402 they provide both a resistive and capacitance tamper detection layer that can be sensed by on-chip circuits for interference/tampering and/or physical modification. The co-integrated MIM capacitors of FIG. 9 and together with TIVs 228 fabricated around the die sidewall edges as shown in FIGS. 5 and 7 can prevent the whole chiplet die 212 from some forms of attack/probing not only from the sidewalls, but also from surfaces.

Further, in the detailed cross-sectional view of the MIM capacitor 401, there is shown deposited a first low-k interlevel dielectric material (ILD) layer 351 within which is embedded the metallization structures forming the frontside interconnect metal structures 225. A patterned first metal capacitor plate electrode 415 is disposed upon the first ILD 351. A MIM capacitor high-k dielectric material layer 418 is conformally disposed over the patterned first electrode 415. The MIM capacitor first dielectric layer 418 entirely covers the patterned first electrode 415 as well as exposed portions of the first low-k ILD 351. A patterned second MIM capacitor plate electrode 420 is conformally disposed over the capacitor first dielectric layer 418 and is substantially parallel-planar with the first MIM cap electrode 415. A further high-k capacitor dielectric layer 424 is conformally disposed over the patterned second electrode 420. A second low-k interlevel dielectric (ILD) material layer 371 is disposed over the capacitor second dielectric layer 424. Formed above low-k ILD material layer 371 is a second MIMcap 402 also having: a patterned first metal capacitor plate electrode 455 disposed upon the second ILD 371, a MIM capacitor high-k dielectric material layer 458 that is conformally disposed over the patterned first electrode 455, a MIM capacitor first dielectric layer 458 entirely covers the patterned first electrode 415 as well as exposed portions of the second low-k ILD 371, a patterned second MIM capacitor plate electrode 460 that is conformally disposed over the capacitor first dielectric layer 458 and is substantially parallel-planar with the first MIM cap electrode 455, and a further high-k capacitor dielectric layer 464 that is conformally disposed over the patterned second electrode 460. FIG. 9 shows a third low-k interlevel dielectric material layer 391 disposed over the formed second mid-via MIMcap 402.

Although not shown in the close-up view of the MIM capacitors 360 shown in FIG. 9, the vertical via portions of frontside interconnect metal structures 225 electrically contact the mid-via level metal plate 305. Additionally, a frontside interconnect metal structure 225 can extend through and opening formed in the mid-via metal plate 305 without contacting the mid-via metal plate. In an embodiment, frontside interconnect metal layer structures 225A, 225B are shown extending vertically through the low-k dielectric material layer 391 and through the second low-k dielectric material layer 371 and electrically contacts the first MIM capacitor electrode 415 of first MIMcap 401. Similarly, a frontside interconnect metal structure 225B is shown extending vertically through the low-k dielectric material layer 391 and through low-k dielectric material layer 371 and electrically contacting the second MIM capacitor electrode 420 of the first MIMcap 401. In this embodiment, both frontside interconnect metal structures 225A, 225B extend through high-k dielectric material layers 458, 464 and through respective openings 440 formed in the first and second electrodes 455, 460 of the second MIMcap 402 and can further extend down through low-k dielectric material layer 351 for respective electrical connections to the die 212. In the close-up, cross-section view of FIG. 9, other frontside interconnect metal structures 225C, 225D are shown extending vertically through the low-k dielectric material layer 391 with frontside interconnect metal structure 225C contacting electrode 455 of the second MIMcap 402 and frontside interconnect metal layer structure 225D contacting electrode 460 of the second MIMcap 402. Both frontside interconnect metal layer via structures 225C, 225D are shown further extending vertically through the low-k dielectric material layers 371 and through portions of high-k dielectric material layers 418, 424 and through low-k dielectric material layer 351 for connection to the die 212. Depending on the implementation, the frontside interconnect metal layer via structures 225C, 225D can extend through more or less low-k dielectric material layers than what is depicted.

In an embodiment, the mid-via metal plate 305 co-integrated with MIM capacitors 350 provides a resistive and capacitance tamper detection layer that can be sensed by on-chip circuits for interference/tampering and/or physical modification. Thus, although not shown in FIG. 9, some frontside interconnect metal layer structures 225 that electrically contact the mid-via level metal plate 305 (or top and bottom plates of MIM cap 402) can extend down to electrically contact and/or connect to a backside mid-via level metal plate 306. However, alternatively and/or in addition, the frontside interconnect metal layer structures 225, e.g., 225C, 225D, that electrically contact the mid-via level metal plate 305 (or top and bottom plates of MIM cap 402) can extend down to electrically contact and/or bond metal structure at surface of the die 212 that can conduct signals to an on-chip sensing circuit 375 that sense signals that can be used to detect interference/tampering and/or physical modification of the chiplet/die. The low-k dielectric material between tamper MIMcap 402 and power MIMcap 401 reduces noise coupling to a power grid (not shown) and it can even reduce coupling between the two MIMcaps and their fabrication is also a reduced cost solution. Further, co-integration of the EM metal shield 305 and the two MIMcap structures 350 separated with the low-k dielectric material layer 371 and between the EM shield 305 and second tamper MIMcap 402 separated with low-k dielectric material layer 391 with both EM shield and both MIMcaps 401, 402 located between the same BEOL metal layers reduces noise coupling to a power grid. The EM shield can be wired separately from an adjacent power grid and may be sensed by circuits for interference (tampering); alternatively, the EM shield may just be connected to the backside EM metal shield. Further, in view of FIG. 9, the tamper resistance and MIMcaps 401, 402 wired separately from power grid may be sensed by circuits for interference/tampering and physical modification. The co-integration with MIMcap enable reduced cost and reduced coupling to adjacent wiring layers

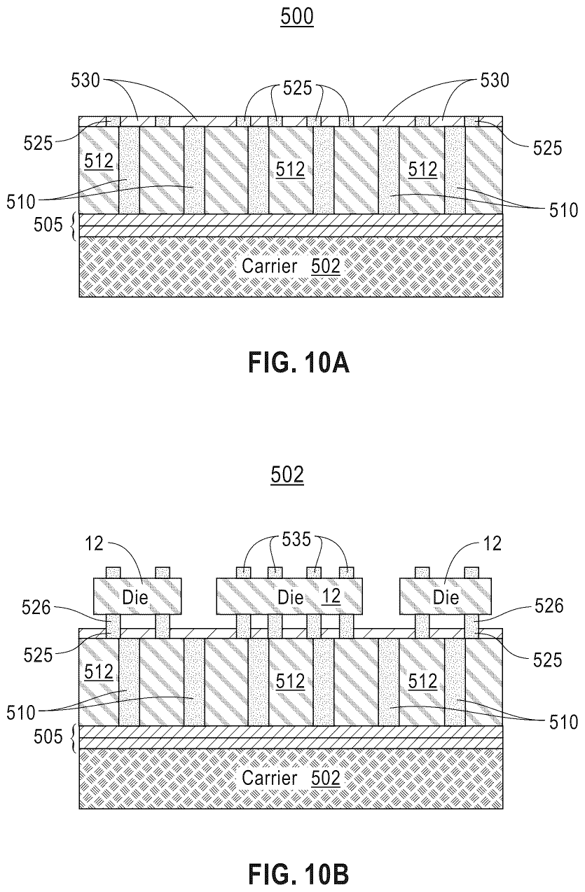

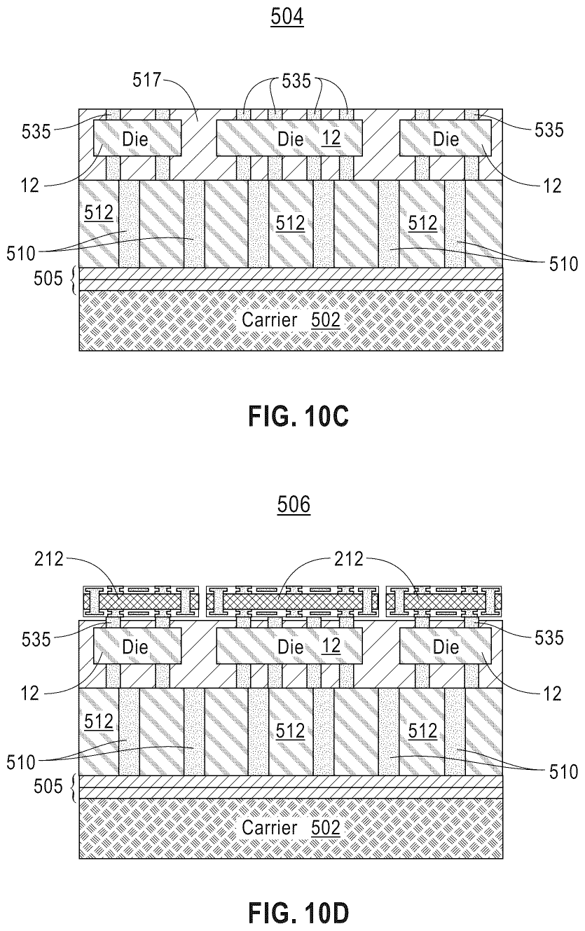

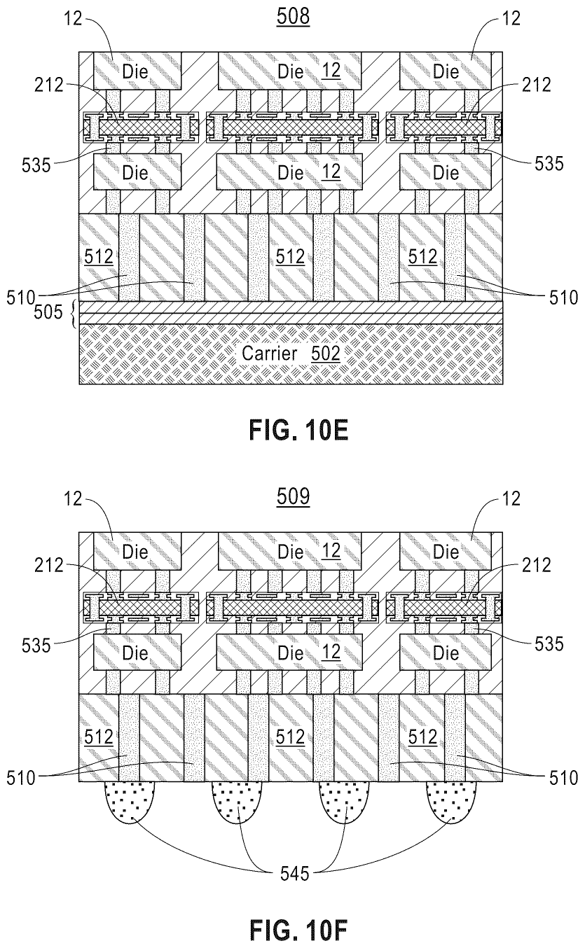

FIGS. 10A-10F depict an exemplary process for fabricating a stacked 3D semiconductor die structure including active chiplets and attached EM shields according to embodiments herein.

As shown in FIG. 10A, there is depicted a semiconductor or insulating material wafer or carrier 502, that is adhesively bonded to a semiconductor substrate 512 using one or more adhesive bonding layers 505. In an embodiment, the substrate could be organic, glass, silicon, etc. If it is a silicon interposer, it would be formed in a standard process, TSVs, BEOL wiring, etc. It might follow a CoWoS process. If it is an organic substrate (e.g., laminate), it could be a fully formed substrate using redistribution layer processing, or it could even be a fanout package. Semiconductor substrate 512 includes one or more metal pillars 510 fabricated therein that extend vertically within substrate 512 from top surface to bottom surface thereof. Formed on top substrate 510 are one or more additional Cu pads 525 and filling materials 530.

FIG. 10B shows a resulting structure 502 after performing steps to attach a first tier of dies 12 to pad locations along a top surface of the chiplet die stack of carrier 502 FIG. 10A. In FIG. 10B, underneath each die 12 is Cu pads 526 for Cu—Cu bonding that are attached (bonded) to bottom Cu pads 525 on the carrier.

FIG. 10C shows a resulting structure 504 after performing steps to fill a low-k dielectric gap fill material 517 between the first tier dies 12 and as a result of a further surface chemical-mechanical polish (a polish down) step. Further formed on top a respective die 12 is one or more metal bonding structures, e.g., Cu pads or landings 535.

After forming structure 504 of FIG. 10C, there can be performed steps for forming EM shielded chip/chiplet tier-2 dies in accordance with embodiments herein depicted in either FIGS. 3, 5, 7 and 9. That is, an array of chip/chiplet dies 212 forming tier 2 dies are formed on a separate wafer, and formed at each chip/chiplet die on a separate wafer is the EM shield as depicted according to the various embodiments herein. The chip/chiplet dies with formed tip, bottom and TIV sidewall shielding are diced according to known techniques in an embodiment to form individual EM shielded dies 212, e.g., top/bottom metal mesh or plates whether co-integrated or not with a MIM-cap. Any formed backside metal contact structures of a tier 2 die 212 can then be aligned with top surface Cu pads 535 on the first tier dies for mechanical/electrical bonding thereto. In an embodiment, a fabricated logic chip/chiplet 12 can be an integrated circuit (IC) such as a graphics processing unit (GPU) or central processing unit (CPU), logic die, memory die, etc.

FIG. 10D shows a resulting structure 506 after an alignment and Cu—Cu bonding of a respective EM shielded (tier 2) die 212 to a respective die 12 at the tier below (tier 1). That is, as a result of forming shielded die 212, bottom metal pad contact bonding structures are formed that align with the top surface Cu pads 535 formed on the top surfaces of respective first tier dies 12 and are exposed at the surface of intermediate structure 504 of FIG. 10C.

FIG. 10E shows a resulting structure 508 after bonding a further tier of dies 12, e.g., tier 3, on top the set of EM shielded dies 212 stacking, e.g., by hybrid bonding or thermal compression bonding (solder bonding) to tier 2 dies. As shown in FIG. 10E, a respective further tier 3 die 12 includes bottom metal contact pads that connect to respective pads formed at a top surface of the tier 2 EM shielded dies 212. FIG. 10E further shows the resulting structures after filling gaps between dies, (or more tier) die attachments.

FIG. 10F shows a resulting structure 509 resulting from further processing steps to detach the carrier structure 502 from the chip/chiplet stack arrangement and remove the adhesive layers, and form underbumps, e.g., C4 bumps 545 in communication with a respective Cu pillars 510.

While the figures herein illustratively demonstrate exemplary structures and processing steps, according to specific embodiments of the present invention, it is clear that a person ordinarily skilled in the art can readily modify such structures or process steps for adaptation to specific application requirements, consistent with the above descriptions.

It should therefore be recognized that the present invention is not limited to the specific embodiment illustrated hereinabove, but rather extends in utility to any other modification, variation, application, and embodiment, and accordingly all such other modifications, variations, applications, and embodiments are to be regarded as being within the spirit and scope of the invention.

What is claimed is:

1. An electromagnetic (EM) shielding apparatus for a semiconductor die comprising;
a top metal shield structure disposed in an interlevel dielectric material layer above a top surface of the semiconductor die, the top metal shield structure disposed at a frontside metal interconnect level within the interlevel dielectric material layer, the interlevel dielectric material layer comprising a low-k dielectric material;
a bottom metal shield structure disposed in an interlevel dielectric material layer below a bottom surface of the semiconductor die, the bottom metal shield structure disposed at a backside metal interconnect level; and
a side metal via having a first connection to the top metal shield structure at the frontside metal interconnect level and a second connection to the bottom metal shield structure at the backside metal interconnect level, said side metal via extending from the top metal shield structure to the bottom metal shield structure through a dielectric material portion of the semiconductor die.

2. The apparatus as claimed in claim 1, further comprising: at least one frontside metal interconnect structure disposed in the interlevel dielectric material layer above the top surface of the semiconductor die, the frontside metal interconnect structure comprising a top metal layer and a metal via connected to the top metal layer of the at least one frontside metal interconnect structure, the top metal shield structure being formed at a via-level height above the top surface of the semiconductor die corresponding to the metal via connecting the top metal layer of the at least one frontside metal interconnect structure.

3. The apparatus as claimed in claim 2, wherein the top metal shield structure comprises a planar metal mesh.

4. The apparatus as claimed in claim 2, wherein the top metal shield structure comprises a planar metal plate.

5. The apparatus as claimed in claim 2, wherein the top metal structure comprises a plurality of metal lines forming an orthogonal or angled cross-hatch pattern.

6. The apparatus as claimed in claim 2, wherein the metal via extending from the top metal structure to the bottom metal structure through a dielectric material portion of the semiconductor die is located at a crack stop location of said die.

7. The apparatus as claimed in claim 2, wherein the top metal shield structure comprises a connection to one or more isolated metal layers separate from a power grid.

8. The apparatus as claimed in claim 2, wherein the metal via of the at least one frontside metal interconnect structure is electrically bonded to a corresponding metal structure at a top surface of the semiconductor die, said top metal shield structure comprising openings formed therein, wherein the metal via of the at least one frontside metal interconnect structure extends through the low-k dielectric material and through a corresponding formed opening.

9. The apparatus as claimed in claim 8, wherein the at least one frontside metal interconnect structure comprises:
a first frontside metal interconnect structure and a second frontside metal interconnect structure disposed spaced apart in the interlevel dielectric material layer above the top surface of the semiconductor die and each first and second frontside metal interconnect structure comprising a top metal layer and a metal via connected to the top metal layer; the shielding apparatus further comprising:
a metal-insulator-metal capacitor (MIMcap) having a first metal plate and a second metal plate and a high-k dielectric material therebetween, the first metal plate connecting a metal via of the first frontside metal interconnect structure and the second metal plate connecting a metal via of the second frontside metal interconnect structure, the MIMcap being co-integrated with the top metal shield structure and disposed below the top metal shield structure at a via-level height above the top surface of the semiconductor die and separated from the top metal shield structure by said low-k dielectric material.

10. The apparatus as claimed in claim 9, wherein the at least one frontside metal interconnect structure comprises:
a third frontside metal interconnect structure and a fourth frontside metal interconnect structure disposed spaced apart in the interlevel dielectric material layer above the top surface of the semiconductor die and each third and fourth frontside metal interconnect structure comprising a top metal layer and a metal via connected to the top metal layer, the top metal shield structure electrically connected to the third frontside metal interconnect structure and fourth frontside metal interconnect structure; the shielding apparatus further comprising:
a sensing circuit for sensing an electrical property of the top metal shield structure, said electrical property used to detect an incidence of tampering, wherein the sensing circuit is electrically connected to both said third frontside metal interconnect structure and fourth frontside metal interconnect structure, wherein the top metal shield structure co-integrated with the MIM capacitor and together with the side metal via at the sidewall edge prevents the semiconductor die from a probing attack.

11. An electromagnetic (EM) shielding apparatus for a semiconductor die comprising;
a metal shield structure disposed in an interlevel dielectric material layer either above a top surface of the semiconductor die or below a bottom surface of the semiconductor die, the interlevel dielectric material layer comprising a low-k dielectric material;
a first metal interconnect structure and a second metal interconnect structure, each first and second metal interconnect structure disposed spaced apart in the interlevel dielectric material layer either above the top surface or below the bottomsurface of the semiconductor die and each first and second metal interconnect structure comprising a metal layer and a metal via connected to the metal layer, the metal shield structure disposed at a height corresponding to a via-level height of the first and second metal interconnect structures formed within the interlevel dielectric material layer; and
a first metal-insulator-metal capacitor (MIMcap) having a first metal plate and a second metal plate and a high-k dielectric material therebetween, the first metal plate connecting the metal via of the first metal interconnect structure and the second metal plate connecting the metal via of the second metal interconnect, the first MIMcap being disposed below the metal shield structure and separated therefrom by the low-k dielectric material.

12. The apparatus as claimed in claim 11, wherein the metal shield structure is a top metal shield disposed above the top surface of the semiconductor die, and said first and second metal interconnect structures comprising frontside metal interconnect structures disposed above the top surface of the die, said apparatus further comprising:
a bottom metal shield structure disposed in an interlevel dielectric material layer below the bottom surface of the semiconductor die, the bottom metal structure disposed at a backside metal interconnect level; and
a side metal via having a first connection to the metal shield structure at the frontside metal interconnect level and a second connection to the bottom metal shield structure at the backside metal interconnect level, said side metal via extending from the top metal shield structure to the bottom metal shield structure through a dielectric material portion of the semiconductor die, wherein the top metal shield structure is co-integrated with the first MIM capacitor at the vial-level height at the sidewall edge prevents the semiconductor die from a probing attack.

13. The apparatus as claimed in claim 11, further comprising:
a third metal interconnect structure and a fourth metal interconnect structure, each third and fourth metal interconnect structure disposed spaced apart in the interlevel dielectric material layer either above the top surface of the semiconductor die or below the bottom surface of the semiconductor die, and each third and fourth frontside metal interconnect structure comprising a metal layer and a metal via connected to the metal layer, the metal shield structure electrically connected to the third metal interconnect structure and fourth metal interconnect structure; the shielding apparatus further comprising:
a second metal-insulator-metal capacitor (MIMcap) having a first metal plate and a second metal plate and a high-k dielectric material therebetween, the first metal plate of the second MIMcap connecting the metal via of the third metal interconnect structure and the second metal plate of the second MIMcap connecting the metal via of the fourth metal interconnect, the second MIMcap being disposed below the metal structure and separated therefrom by the low-k dielectric material.

14. The apparatus as claimed in claim 12, wherein the metal shield structure is a planar mesh.

15. The apparatus as claimed in claim 12, wherein the metal shield structure comprises a plurality of metal lines forming an orthogonal or angled cross-hatch pattern.

16. The apparatus as claimed in claim 12, wherein the metal shield structure comprises a planar metal plate.

17. The apparatus as claimed in claim 12, wherein the metal shield structure comprises a connection to one or more isolated metal interconnect layers separate from a power grid.

18. The apparatus as claimed in claim 13, further comprising:
a sensing circuit for sensing an electrical property of the metal shield structure, said electrical property used to detect an incidence of tampering, wherein the sensing circuit is electrically connected to both said third metal interconnect structure and the fourth metal interconnect structure.

19. An electromagnetic (EM) shielding apparatus for a semiconductor die comprising;
a first metal interconnect structure and a second metal interconnect structure, each first and second metal interconnect structure disposed in an interlevel dielectric material layer either above a top surface of the semiconductor die or below a bottom surface of the semiconductor die, and each first and second metal interconnect structure comprising a metal layer and a metal via connected to the metal layer, the metal shield structure disposed at a height corresponding to a via-level height of the first and second metal interconnect structure formed within the interlevel dielectric material layer;
a first metal-insulator-metal capacitor (MIMcap) having a first metal plate and a second metal plate and a high-k dielectric material therebetween, the first metal plate of the first MIMcap connecting the metal via of the first metal interconnect structure and the second metal plate of the first MIMcap connecting the metal via of the second metal interconnect, the first MIMcap being disposed at the via-level height below the metal shield structure and separated therefrom by the low-k dielectric material;
a third metal interconnect structure and a fourth metal interconnect structure, each third and fourth metal interconnect structure disposed spaced apart in the interlevel dielectric material layer either above the top surface of the semiconductor die or below the bottom surface of the semiconductor die and each third and fourth metal interconnect structure comprising a metal layer and a metal via connected to the metal layer; and
a second metal-insulator-metal capacitor (MIMcap) having a first metal plate and a second metal plate and a high-k dielectric material therebetween, the first metal plate of the second MIMcap connecting the metal via of the third metal interconnect structure and the second metal plate of the second MIMcap connecting the metal via of the fourth metal interconnect, the second MIMcap being disposed at the via-level height below the first MIMcap and separated therefrom by the low-k dielectric material.

20. The apparatus as claimed in claim 19, further comprising:
a sensing circuit for sensing an electrical property of the second MIMcap, said electrical property used to detect an incidence of tampering, wherein the sensing circuit is electrically connected to both said third metal interconnect structure and the fourth metal interconnect structure.
